(19) United States
(12) Patent Application Publication
(10) Pub. No.: US 2023/0200265 A1
(43) Pub. Date: Jun. 22, 2023

(54) SELECTIVE ENCAPSULATION OF MEMRISTIVE ELEMENT

(71) Applicant: International Business Machines Corporation, Armonk, NY (US)

(72) Inventors: Kevin W. Brew, Niskayuna, NY (US); Injo Ok, Loudonville, NY (US); Sanjay C. Mehta, Niskayuna, NY (US); Matthew T. Shoudy, Guilderland, NY (US); Nicole Saulnier, Slingerlands, NY (US); Iqbal Rashid Saraf, Glenmont, NY (US)

(21) Appl. No.: 17/552,429

(22) Filed: Dec. 16, 2021

(51) Int. Cl. H01L 45/00; H01L 27/24

(52) U.S. Cl. CPC H01L 45/06; H01L 45/145; H01L 45/1675; H01L 45/1691; H01L 45/1253; H01L 45/1608; H01L 45/1683; H01L 27/2463

(57) ABSTRACT

A phase change memory structure including a bottom electrode; a top electrode; a first phase change material between the bottom electrode and the top electrode; a first dielectric surrounding the first phase change material; a second dielectric surrounding the top electrode, the second dielectric having selective adhesion to a metal as compared to the first phase change material; a first metal feature contacting the bottom electrode; and a second metal feature contacting the top electrode.

### BACKGROUND

The present disclosure relates generally to a memristive technologies, and more particularly to a selective encapsulation of a phase change material in a memristive device.

Memristive devices are analog electrical resistance switches that can retain a state of internal resistance based on the history of applied voltage and current.

One class of memristor devices includes non-linear two-terminal resistance switches. Many two-terminal memristive technologies (e.g., Resistive Memories (RRAIVI), Phase-Change Memories (PCM), Conductive Bridging Random Access Memory (CBRAM), Magnetoresistive RAM (MRAM)) utilize subtractive patterning to encapsulate a material with memristive properties and a top electrode metal for self-alignment. Subsequent encapsulation is typically done with multiple dielectric materials such as a higher-k material (e.g., Silicon nitride (SiN) and Silicon dioxide (SiO₂)) with a higher resistivity metal nitride as a top electrode. The combination of a bulk top electrode of higher resistance with a higher capacitance dielectric surrounding it can lead to higher RC time constants when inserting these types of devices into MOL/early BEOL. With higher RC, the read operation of these devices can be significantly limited, preventing nanosecond operation. The higher-k dielectric materials can also reduce the ability to locate multiple PCM devices closely to one another due to higher thermal conductivity than low-k materials (e.g., a carbon-doped silicon oxide (SiCOH)) resulting in thermal leakage programming between PCM devices.

### BRIEF SUMMARY

According to embodiments of the present invention, a phase change memory structure includes a bottom electrode; a top electrode; a first phase change material between the bottom electrode and the top electrode; a first dielectric surrounding the first phase change material; a second dielectric surrounding the top electrode, the second dielectric having selective adhesion to a metal as compared to the first phase change material; a first metal feature contacting the bottom electrode; and a second metal feature contacting the top electrode.

According to at least one embodiment, a method of manufacturing a memristive device includes: providing a base device, the base device can comprise a substrate, a first interlevel dielectric (ILD) layer, and a plurality of bottom metal features; forming a second ILD layer; forming a plurality of first electrodes in the second ILD layer contacting the plurality of bottom metal features; depositing an memristive material stack on the plurality of first electrodes; depositing a top electrode material having a low resistivity on the plurality of memristive material stacks; etching portions of the memristive material stack and the top electrode material to form patterned memristive material stacks and a plurality of top electrodes; depositing a dielectric encapsulation that has a height at least sufficient to cover sidewalls of the memristive material stack and having selective adhesion to a metal as compared to the plurality of memristive material stacks; and depositing a backfill on the dielectric encapsulation around the plurality of top electrodes, the backfill configured to reduce a thermal coupling among the plurality of top electrodes.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof can be implemented in the form of a computer program product including a computer readable storage medium with computer usable program code for performing the method steps indicated. Furthermore, one or more embodiments of the invention or elements thereof can be implemented in the form of a system (or apparatus) including a memory, and at least one processor that is coupled to the memory and operative to perform exemplary method steps. Yet further, in another aspect, one or more embodiments of the invention or elements thereof can be implemented in the form of means for carrying out one or more of the method steps described herein; the means can include (i) hardware mod-ule(s), (ii) software module(s) stored in a computer readable storage medium (or multiple such media) and implemented on a hardware processor, or (iii) a combination of (i) and (ii); any of (i)-(iii) implement the specific techniques set forth herein.

Techniques of the present invention can provide substantial beneficial technical effects. Some embodiments may not have these potential advantages and these potential advantages are not necessarily required of all embodiments. For example, one or more embodiments may provide for:
forming selective dielectric around a memristive device active material (e.g., PCM);
High-k spacer free top electrode and subsequent low-k backfill around top electrode
memristive devices including low RC top electrodes;
a encapsulation etchback needed for a simple integration as a passthrough via on phase; change material does not need its own nitrogen pull to make contact;
low-k, low thermal transport dielectric around a top electrode to reduce/prevent local heat loss when scaling PCM down vertically.

These and other features and advantages of the present invention will become apparent from the following detailed description of illustrative embodiments thereof, which is to be read in connection with the accompanying drawings.

### BRIEF DESCRIPTION OF THE DRAWINGS

Preferred embodiments of the present invention will be described below in more detail, with reference to the accompanying drawings:

FIG. 1 illustrates methods of forming a memristive device according to one or more embodiments of the present invention; and

FIGS. 2-8 are cross-section views of a memristive device at different steps in a manufacturing process according to one or more embodiments of the present invention.

### DETAILED DESCRIPTION

According to embodiments of the present invention, a memristive device includes a top electrode is formed of a low resistivity metal (such as Tungsten (W)), an interlayer liner for etch-stop/adhesion, and an encapsulant (e.g. SiN/SiO₂) with selective adhesion to a memristive material stack versus the top electrode. According to at least one embodiment, the top electrode has a resistivity of about 2-200 microohms centimeter (pohm-cm) (e.g., for copper (Cu) on physical vapor deposition (PVD) Titanium nitride (TiN)). According to some aspects, the interlayer liner may function as a thermal barrier, e.g., an amorphous carbon material. According to some embodiments, the memristive device includes a liner on the top electrode that improves adhesion of a dielectric and/or barrier for subsequent metal wiring. According to some embodiments, the memristive device includes a liner formed on the top electrode by a process such as UV—NH3, plasma nitridation, etc., that converts a metal surface of the top electrode to a nitride (e.g., Tungsten nitride (WN)). According to some embodiments, the memristive device includes a backfill low-k material (e.g. OMCTS 2.7) over the top electrodes.

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

SiN is typically used to encapsulate with tetraethyl orthosilicate (TEOS) backfill, and any etch to contact the top electrode selectively etches the encapsulated sidewall. This integration risks the etch contacting the memory materials. According to some embodiments, a selective top-electrode/encapsulating layer allows for an even backfill of TEOS, and reduces or eliminates preferential sidewall etch of a phase change material.

According to some embodiments, a low-k dielectric is formed around a memristive device top electrode on a phase change material.

According to some embodiments, a selective dielectric deposition encapsulates a memristive device stack.

According to some embodiments, a memristive device includes a low RC top electrode.

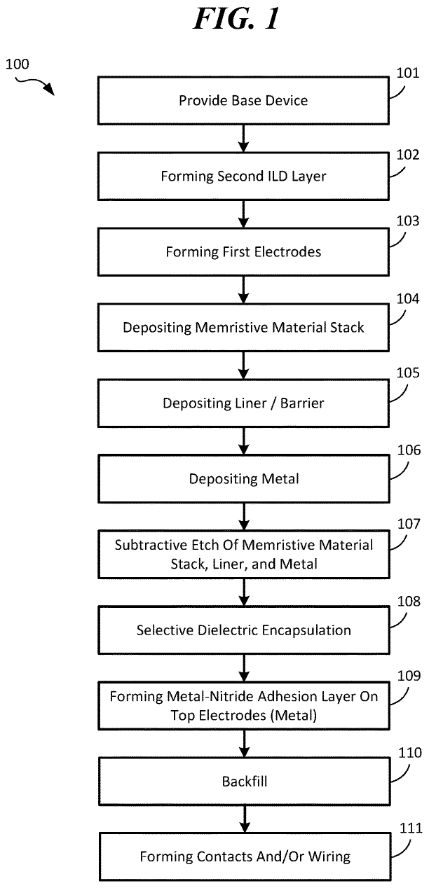

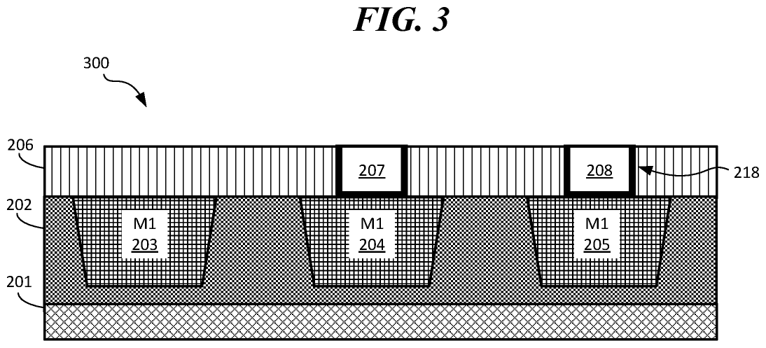

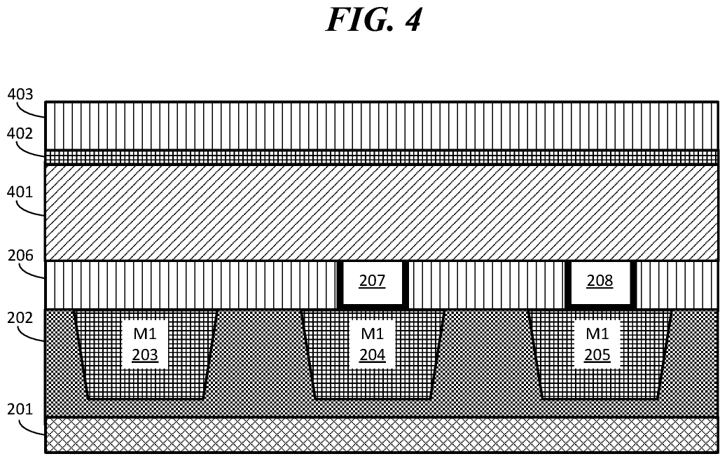

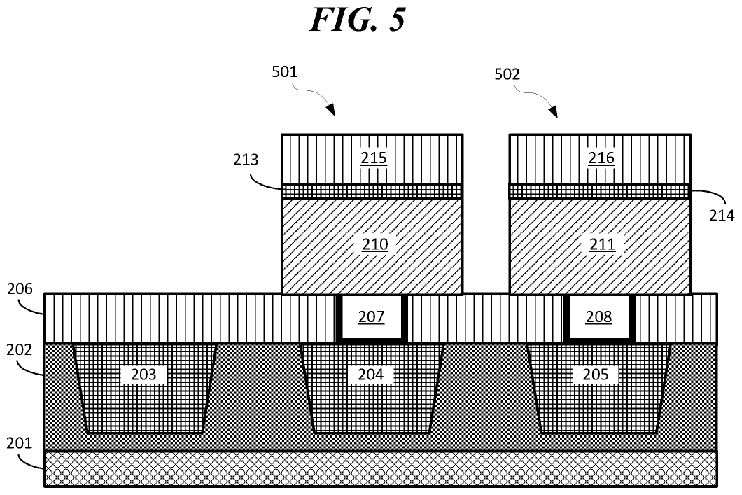

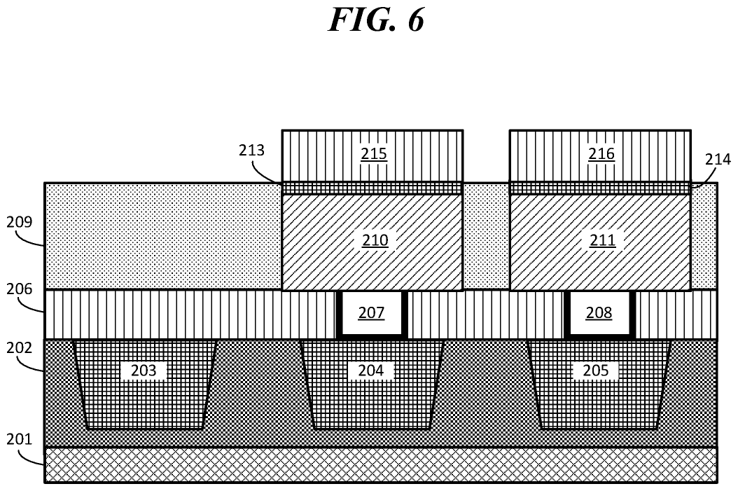

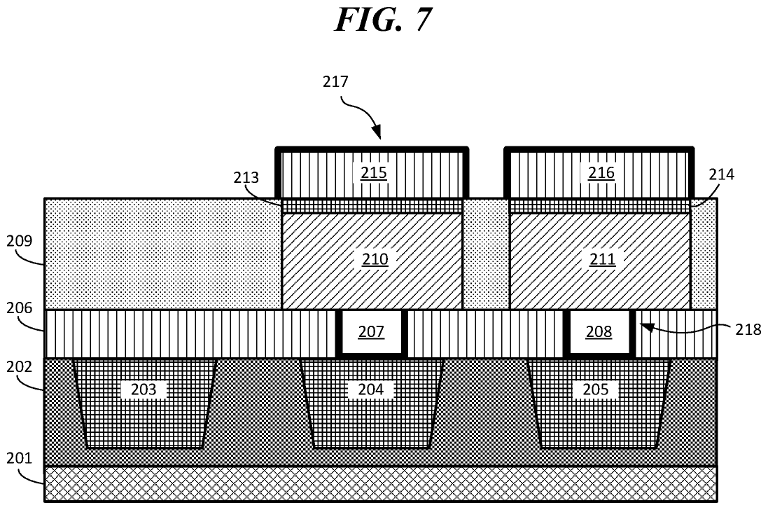

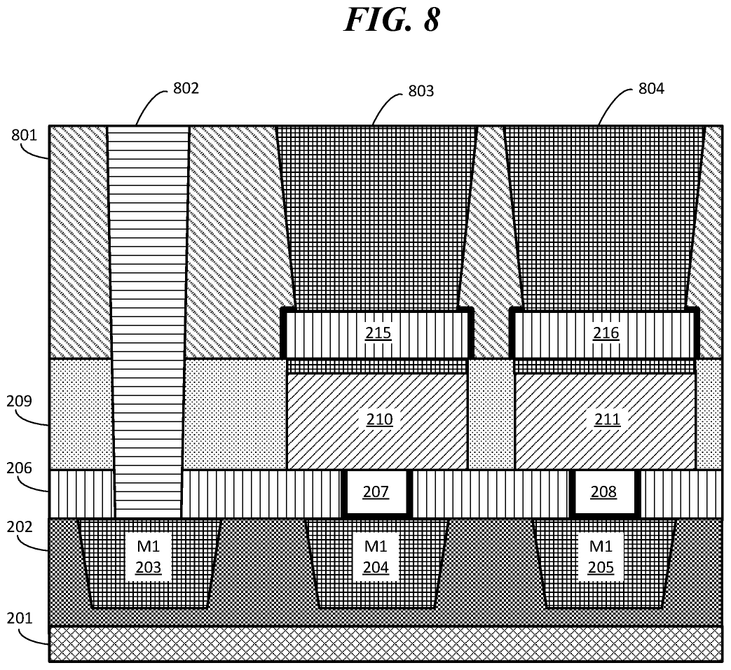

According to some embodiments and referring to FIG. 1, a method 100 of manufacturing a memristive device comprises provide a base device at step 101. According to some embodiments, the base device can comprise a substrate, a first interlevel dielectric (ILD) layer, and a plurality of bottom metal features M1. According to some embodiments, the method 100 includes forming a second ILD layer at step 102, which include depositing and patterning an ILD material, and forming a plurality of first electrodes at step 103 in the second ILD, for example, by depositing a metal material and removing an overburden (e.g., by CMP) (see also FIG. 3). According to some embodiments, the method 100 includes sequentially depositing a memristive material stack at step 104, a liner (e.g., an amorphous carbon material) at step 105, and a metal material at step 106 (see also FIG. 4). The memristive stack and the metal material can be deposited, for example, by physical vapor deposition (PVD). According to some embodiments, the method 100 includes a subtractive etch at step 107 of the memristive material stack, the liner, and the electrode material (see also FIG. 5), and a selective dielectric encapsulation at step 108, which has a height at least sufficient to cover sidewalls of the memristive material stack (see also FIG. 6). According to some embodiments, the method 100 includes forming a metal-nitride adhesion layer on the top electrodes (i.e., etched metal) at step 109 (see also FIG. 7), and performing a backfill at step 110, e.g., depositing a low-K dielectric material (see also FIG. 8). According to some aspects, the backfill at step 110 may include a planarization; the planarization may be omitted, e.g., in a case of a small (e.g., less than about 25 nm height) top electrode. According to some embodiments, the method 100 includes a metal level patterning at step 111, for example, forming contacts and or wiring features (see also FIG. 8).

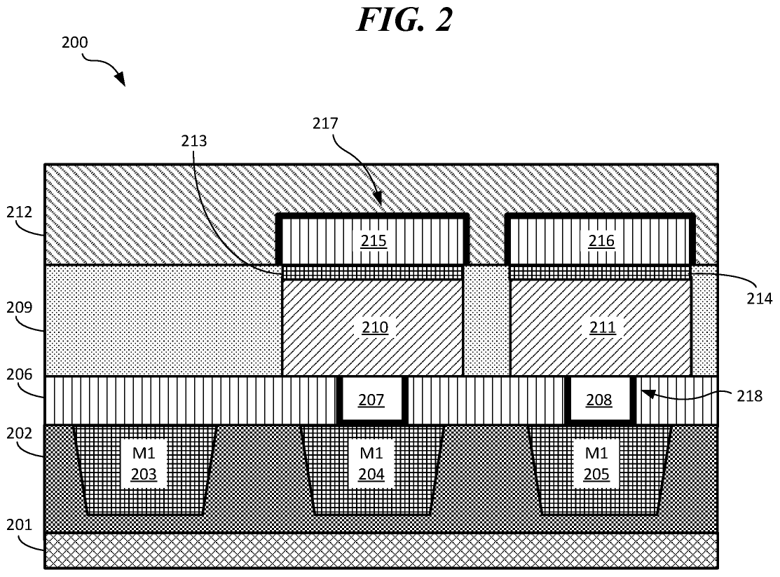

According to some embodiments and referring to FIG. 2, a memristive device 200 comprises a substrate 201, a first ILD layer 202, a plurality of bottom metal features M1 (e.g., read lines, write lines, etc.) in the first dielectric layer including a first metal feature 203, a second metal feature 204, and a third metal feature 205, a second ILD layer 206, and a plurality of first bottom electrodes in the second ILD layer. The first electrodes can include a first bottom electrode 207 and a second bottom electrode 208.

According to at least one embodiment, the first ILD layer 202 may be a SiO2, such as TEOS or fluorinated tetraethyl orthosilicate (FTEOS), or a low-K material, such as SiCOH or ultra low-k (ULK) dielectrics (e.g., ULK 2.7), etc. According to some embodiments, the plurality of bottom metal features M1 may be formed of metals containing any of Ruthenium (Ru), W, Copper (Cu), TiN, Tantalum nitride (TaN) (e.g., liner+metal), etc.

According to some embodiments, the memristive device 200 further comprises an encapsulation 209 (e.g., a SiN material selectively deposited) on the second ILD layer, and a plurality of memristive stacks in the selective encapsulation including a first memristive stack 210 and a second memristive stack 211. According to some embodiments, the plurality of memristive stacks can be formed of a phase change material such as GST 225 (germanium-antimony-tellurium or GST).

According to some embodiments, the memristive device 200 further comprises a second ILD layer 212 (e.g., a low-K ILD) on the selective encapsulation layer, and a plurality of top electrodes (e.g., formed of Tungsten (W)) including a first top electrode 215 and a second top electrode 216. According to at least one embodiment, the second ILD layer 212 (e.g. SiCOH) improves a thermal isolation between the first memristive stack 210 and the second memristive stack 211, and reduces a wiring capacitance of the top electrodes. For example, intrinsic to low-K material typically includes voids leading to higher thermal resistivity (i.e., than other dielectric materials); therefore, while heat can transport between the second ILD layer 212 and the encapsulation 209, in some aspects where the second ILD layer 212 is a low-K material, the thermal isolation of the memristive stacks is improved.

According to some embodiments, a first liner 213 and a second liner 214 disposed between the plurality of memristive stacks and the plurality of top electrodes. According to at least one embodiment, the first liner and the second liner can be omitted.

According to at least one embodiments, a nitride liner (e.g., first nitride liner 217 and second nitride liner 218) can be formed on one or more surfaces of the electrodes (e.g., the first electrodes and the top electrodes). For example, sidewall and top surfaces of the top electrodes can be converted into a nitride liner using techniques such a UV-NH3 or plasma nitridation. According to some embodiments, a metal nitride can be deposited isotropically (e.g., — 30 angstroms by atomic layer deposition of TiN) and etched back from the selective encapsulation.

According to at least one embodiment, a prior deposited dielectric, i.e., the encapsulation 209 formed at step 108, allows for the second ILD layer 212 (e.g., a low-K dielectric) to surround the top electrodes for improved local heat retention within the stack. According to some embodiments, any undercut of the first memristive stack 210, the first liner 213, or the first top electrode 215 from (a lateral etch due to) the subtractive etch at step 107 will be filled by the encapsulation 209 formed at step 108.

According to some aspects, alternate phase change materials can be used. For example, the a phase change memory bridge cell according to some embodiments can include a phase change material such as germanium-antimony-tellurium (GST), gallium-antimony-tellurium (GaST), silver-iridium-antimony-telluride (AIST) material, germanium-tellurium compound material (GeTe), Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, Ge—Te alloys and combinations thereof.

According to example embodiments, the phase change material(s) can be doped (e.g., with one or more of oxygen (O), carbon C, nitrogen (N), silicon (Si), or titanium (Ti)).

According to some embodiments and referring to FIG. 3, a base device 300 of a memristive device is provided. According to some embodiments, the base device can include a substrate 201, a first ILD layer 202, and a plurality of bottom metal features M1. According to some embodiments, the base device can include a second ILD layer 206 and a plurality of first bottom electrodes in the second ILD including the first bottom electrode 207 and the second bottom electrode 208. According to some embodiments, a liner (e.g., a second nitride liner 218) can be deposited in a trench prior to depositing a metal forming the plurality of first electrodes.

According to some embodiments and referring to FIG. 4, a memristive material stack 401, a liner layer 402 (e.g., an amorphous carbon material or Ti), and an electrode material 403 are deposited on the base device. According to at least one embodiment, the liner layer 402 is one or more of an adhesion layer, an atomic barrier layer, and a thermal barrier layer. The memristive stack, the liner, and the metal material can be deposited, for example, by physical vapor deposition (PVD). According to some embodiments, the memristive material stack 401 include a conductor/insulator/conductor thin-film stack. It should be understood that other material sets (i.e., other than a conductor/insulator/conductor thin-film stack) can be used in forming the memristive material stack 401, where the material set may be selected according to the application.

According to some embodiments and referring to FIG. 5, a memristive material stack 401, a liner layer 402 (e.g., an amorphous carbon material), and an electrode material 403 are etched (e.g., by RIE or ion beam etch) for form a first stack 501 on the first bottom electrode 207 including a first memristive stack 210, a first liner 213, and a first top electrode 215, and a second stack 502 on the second bottom electrode 208 including a second memristive stack 211, a second liner 214, and a second top electrode 216. According to some aspects, the first liner 213 and the second liner 214 can be omitted.

According to some embodiments and referring to FIG. 6, the encapsulation 209 is a selective dielectric encapsulation having a height at least sufficient to cover sidewalls of the first memristive stack 210 and the second memristive stack 211. According to some aspects, the encapsulation 209 can be formed by, for example, chemical vapor deposition of SiN. It should be understood that other selective dielectrics can be used, for example, depending on a metal used to form the top electrodes.

According to some embodiments, the encapsulation 209 may include an overburden portion, which is the portion extending higher than the height of the memristive stacks (as illustrated in the figures).

According to some embodiments and referring to FIG. 7, a nitride liner 217 (e.g., a metal-nitride adhesion layer) is formed on the top electrodes. For example, sidewall and top surfaces of the top electrodes can be converted into a nitride liner using techniques such a UV-NH3 or plasma nitridation. According to some embodiments, the nitride liner 217 can be deposited isotropically (e.g., ˜30 angstroms by atomic layer deposition of TiN) and etched back from the selective encapsulation.

According to some embodiments and referring to FIG. 8, a low-K dielectric material 801 is deposited as a backfill. According to at least one embodiments, the low-K dielectric material 801 is located on the encapsulation 209 and between the top electrodes. According to some embodiments, a contact 802 can be formed contacting a first metal feature 203 (e.g., a read line). According to some embodiments, additional metal features, e.g., a first metal feature 803 and a second metal feature 804, can be formed contacting the top electrodes. According to some embodiments, these metal features can be metal contacts, vias, wiring lines, etc.

According to at least one embodiment, even in a case where the first metal feature 803 is wider than the first top electrode 215 or the second top electrode 216, the first memristive stack 210 and the second first memristive stack 211 have been previously encapsulated by the encapsulation 209.

Recapitulation:

According to embodiments of the present invention, a phase change memory structure includes: a bottom electrode (first bottom electrode 207); a top electrode (first top electrode 215); a first phase change material [210] between the bottom electrode and the top electrode; a first dielectric [encapsulation 209] surrounding the first phase change material; a second dielectric (low-K dielectric material 801) surrounding the top electrode, the second dielectric having selective adhesion to a metal as compared to the first phase change material; a first metal feature (second metal feature 204) contacting the bottom electrode; and a second metal feature (first metal feature 803) contacting the top electrode.

According to at least one embodiment, a method of manufacturing a memristive device includes: providing a base device (at step 101), the base device can comprise a substrate, a first interlevel dielectric (ILD) layer, and a plurality of bottom metal features; forming a second ILD layer (at step 102); forming a plurality of first electrodes (at step 103) in the second ILD layer contacting the plurality of bottom metal features; depositing an memristive material stack (at step 104) on the plurality of first electrodes; depositing a top electrode material (at step 106) having a low resistivity on the plurality of memristive material stacks; etching portions of the memristive material stack and the top electrode material (at step 107) to form patterned memristive material stacks and a plurality of top electrodes; depositing a dielectric encapsulation (at step 108) that has a height at least sufficient to cover sidewalls of the memristive material stack and having selective adhesion to a metal as compared to the plurality of memristive material stacks; and depositing a backfill (at step 110) on the dielectric encapsulation around the plurality of top electrodes, the backfill configured to reduce a thermal coupling among the plurality of top electrodes.

The terminology used herein is for the purpose of describing particular embodiments only and is not intended to be limiting of the invention. As used herein, the singular forms “a,” “an” and “the” are intended to include the plural forms as well, unless the context clearly indicates other-wise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A phase change memory structure comprising:
a bottom electrode;
a top electrode having a low resistivity;
a first phase change material between the bottom electrode and the top electrode;
a first dielectric surrounding the first phase change material;
a second dielectric surrounding the top electrode, the second dielectric having selective adhesion to a metal as compared to the first phase change material;
a first metal feature contacting the bottom electrode; and
a second metal feature contacting the top electrode.

2. The phase change memory structure of claim 1, wherein the first phase change material comprises a first memristive stack.

3. The phase change memory structure of claim 1, wherein the first dielectric is a silicon nitride material.

4. The phase change memory structure of claim 1, wherein the second dielectric is a low-K dielectric material, different than the first dielectric.

5. The phase change memory structure of claim 1, wherein the second dielectric thermally isolates the first phase change material from an adjacent second phase change material.

6. The phase change memory structure of claim 1, further comprising a liner between the first phase change material and the top electrode.

7. The phase change memory structure of claim 6, wherein the liner is at least one of an adhesion layer, an atomic barrier layer, and a thermal barrier layer.

8. The phase change memory structure of claim 6, wherein the second dielectric surrounds the liner.

9. The phase change memory structure of claim 1, further comprising:
a first interlevel dielectric surrounding the first metal feature;
a second interlevel dielectric surrounding the bottom electrode;
a third metal feature in the first interlevel dielectric; and
a fourth metal feature in the first dielectric, the second dielectric, and the second interlevel dielectric, and contacting the third metal feature.

10. The phase change memory structure of claim 1, further comprising a first nitride liner on at least one surface of the top electrode.

11. The phase change memory structure of claim 10, wherein the first nitride liner is a metal-nitride adhesion layer.

12. The phase change memory structure of claim 1, further comprising a second nitride liner on at least one surface of the bottom electrode.

13. The phase change memory structure of claim 12, wherein the second nitride liner is a metal-nitride adhesion layer.

14. A method of manufacturing a memristive device comprising:
providing a base device, the base device can comprise a substrate, a first interlevel dielectric (ILD) layer, and a plurality of bottom metal features;
forming a second ILD layer;
forming a plurality of first electrodes in the second ILD layer contacting the plurality of bottom metal features;
depositing an memristive material stack on the plurality of first electrodes;
depositing a top electrode material having a low resistivity on the plurality of memristive material stacks;
etching portions of the memristive material stack and the top electrode material to form patterned memristive material stacks and a plurality of top electrodes;
depositing a dielectric encapsulation that has a height at least sufficient to cover sidewalls of the memristive material stack and having selective adhesion to a metal as compared to the plurality of memristive material stacks; and
depositing a backfill on the dielectric encapsulation around the plurality of top electrodes.

15. The method of claim 14, further comprising forming a plurality of contacts contacting the plurality of top electrodes respectively.

16. The method of claim 14, further comprising forming a nitride liner on the plurality of top electrodes.

17. The method of claim 14, further comprising forming an adhesion layer on the memristive material stack before depositing the top electrode material.

18. The method of claim 14, further comprising depositing a liner layer on the memristive material stack prior to depositing the top electrode material, wherein the etching further forms a liners between each of the patterned memristive material stacks and the plurality of top electrodes.

19. The method of claim 14, wherein the backfill is a low-K dielectric material having a higher thermal resistivity than the dielectric encapsulation.
